(19) United States
(12) Patent Application Publication
(10) Pub. No.: US 2011/0014739 A1
(43) Pub. Date: Jan. 20, 2011

(54) MAKING AN EMISSIVE LAYER FOR MULTICOLORED OLEDS

(76) Inventor: Denis Y. Kondakov, Kendall, NY (US)

Correspondence Address: MCKENNA LONG & ALDRIDGE LLP, 1900 K STREET, NW, WASHINGTON, DC, 20006, US

(21) Appl. No.: 12/504,053

(22) Filed: Jul. 16, 2009

(51) Int. Cl. H01L 21/20

(52) U.S. Cl. 438/35; 257/E21.09

(57) ABSTRACT

A method of making an electroluminescent device having a substrate, and at least one blue light emitting layer and at least one non-emissive layer containing an emissive material that emits light longer in wavelength than blue light, these two layers being directly separated by and in direct contact with a non-emissive buffer layer; and heating the electroluminescent device after fabrication to cause the long wavelength emissive material to diffuse from the non-emissive layer into at least the buffer layer such that the long wavelength emissive material comes into contact with the blue light-emitting layer such that the recombination energy in the emitting layer is preferentially transferred to the diffused emissive material compared to the blue emissive material and the light emitted is longer in wavelength than blue light.

### FIELD OF THE INVENTION

The present invention relates to methods of making multicolored organic light-emitting devices (OLEDs) and, more particularly to methods of providing in a RGB pixellated OLED device, a light-emitting layer whose emission characteristics can be altered by diffusing a second emissive material from a non-emissive layer into contact with the light-emitting layer.

### BACKGROUND OF THE INVENTION

Organic light-emitting devices, also referred to as organic electroluminescent (EL) devices or as organic internal junction light-emitting devices, contain spaced electrodes separated by an organic light-emitting structure (also referred to as an organic EL medium) which emits light in response to the application of an electrical potential difference across the electrodes. At least one of the electrodes is light-transmissive, and the organic light-emitting structure can have a multi-layer of organic thin films which provide for hole injection and transport from an anode, and for electron injection and transport from a cathode, respectively, with light emission resulting from electron-hole recombination at an internal junction formed at an interface between the hole-transporting and the electron-transporting thin films. As employed herein, the term “thin film” refers to layer thicknesses of less than 1 micrometer with layer thickness of less than about 0.5 micrometer being typical. Examples of organic light-emitting devices containing organic light-emitting structures and cathode constructions formed by thin film deposition techniques are provided by commonly-assigned U.S. Pat. Nos. 4,345,429; 4,539,507; 4,720,432; and 4,769,292.

During operation of an organic light-emitting device, the spectral distribution of emitted light (measured in terms of spectral radiance) is related to the electroluminescent properties of the organic thin films used in the construction of the device. For example, if an organic light-emitting structure includes a layer which contains a single light-emitting material capable of sustaining hole-electron recombination, the emitted light will arise from the characteristic light emission from that material. However, the addition of a small amount of fluorescent material capable of emitting light in response to energy released by hole-electron recombination will modify the color of the light emission, and can improve the operational stability of an organic light-emitting device. In analogy to terminology used in the semiconductor industry, fluorescent emissive materials dispersed uniformly at relatively low concentration in light-emitting organic host materials are called “dopants” or “emitters.”

As commonly practiced, the organic thin films of a light-emitting device are formed by vapor deposition (evaporation or sublimation) in successive deposition steps within a vacuum system which employs a deposition rate control. When a fluorescent dopant is to be uniformly incorporated within an organic light-emitting layer, the light-emitting host material and the fluorescent dopant material are co-deposited from two independently controlled deposition sources. It is necessary to control the individual deposition rates of a fluorescent dopant and a host material when a desired dopant concentration in the host material of the organic light-emitting layer is at or near a lower end of a dopant concentration range of 10⁻³ to about 10 mole percent. The difficulty of reliably controlling the deposition rates in a vapor deposition method of an organic light-emitting host material and of a fluorescent dopant material has been an obstacle in the process of reproducibly fabricating organic electroluminescent devices containing a fluorescent dopant or fluorescent dopants. However, alternative methods of doping emissive layers are known.

U.S. Pat. No. 6,641,859 discloses a method for making an emissive layer in an EL device by diffusing a dopant from a dopant-containing layer to a separate dopant receiving layer using heat, thereby forming the emissive layer. The dopant-containing layer and the dopant-receiving layer can be separated by a hole-transporting or electron-transporting layer. In this method, the dopant-receiving layer is not emissive until after heat treatment.

U.S. Patent Application Publication No. 20060231830 describes a display device having a plurality of organic electroluminescence devices arranged on a substrate, each of the devices including a lower electrode, an organic layer at least containing a light emitting layer, and an upper electrode in this order, the light emitting layer of at least some of the organic electroluminescence devices has a first light emitting layer formed by vapor deposition and a second light emitting layer formed by thermal transfer, and the first light emitting layer emits light whose wavelength is equal to or shorter than that of blue light. The thermal transfer occurs during fabrication. For example, a green or red fluorescent dye can be thermally transferred to the blue luminescent layer to provide a green or red emitting device.

U.S. Pat. No. 5,895,692 describes a fabrication process for manufacturing an organic electroluminescent device, including the steps of sequentially forming a hole transport layer, a recombination region layer for electrons and holes of the transport layers is formed, a fluorescent pigment (R, G or B) is applied to an upper surface of the recombination region layer. Subsequently, the fluorescent pigment is heated to be diffused into the recombination layer so that the fluorescent pigment and the recombination layer constitute a luminescent layer. An electron transport layer is provided over the recombination layer.

WO9953529 describes methods involved for patterning pixels wherein dopants can be introduced into an emissive layer by diffusion. The fluorescent dopants are introduced as solutions or from dyed layers.

U.S. Patent Application Publication No. 20030030370 describes an OLED element that is composed of a blue (B) emissive layer, a green (G) emissive layer and a red (R) emissive layer as a set of pixels, the organic electroluminescence element is further characterized in that the B emissive layer contains a B emissive material, the G emissive layer contains B and G emissive materials, and the R emissive layer contains B and G and R emissive materials. A manufacturing method of an organic electroluminescence element is disclosed that comprises steps of: forming a first electrode divided by a plurality of separators and disposed on a substrate in matrix; forming a blue (B) emissive layer on the first electrode by diffusing a B emissive material; obtaining a green (G) emissive layer adjacent to the B emissive layer after diffusing a G emissive material in a part of the B emissive layer; obtaining a red (R) emissive layer adjacent to the G emissive layer after diffusing a R emissive material in a part of the G emissive layer; and forming a second electrode on each of the R and G and B emissive layers. The process occurs during fabrication of the device and not post-fabrication.

Wu et al, Appl. Phys. Let., 83(4), 611 (2003) discloses RGB OLED devices that change color following thermal treatment involving three separate emission zones separated by blocking layers. However, the presence of blocking layers unavoidably results in substantially increased operational voltages for the subpixels of two out of three colors. Presence of blocking layers is also likely to have negative effect on operational stability.

### SUMMARY OF THE INVENTION

It is an object of the present invention to provide an improved method of forming a light-emitting layer in a multicolored OLED device where the color of light emitted can be modified as a function of post-fabrication thermal treatment.

This object is achieved by a method of making an organic electroluminescent device producing at least two colors of light having an anode and a cathode on a substrate, and at least one emission layer, located between the anode and cathode, containing a first emissive material that emits blue light, wherein the improvement comprises:

(a) providing at least one non-emissive layer containing a second emissive material that is capable of emitting light longer in wavelength than blue light and disposed over or under the blue emission layer;

(b) providing a buffer layer between the non-emissive layer and the emissive layer and in direct contact with both; and

(c) heating the electroluminescent device to cause the second emissive material from the non-emissive layer to diffuse into at least the buffer layer so that second emissive material emits light.

In one important embodiment, the non-emissive layer(s) can be patterned prior to diffusing into the blue light-emitting layer, thus producing a patterned, multi-color emissive device. In another important embodiment, a patterned, multi-color emissive device is produced by selectively heating only desired areas in order to modify the color of light produced by those areas.

This method results in a much simplified manufacturing process, including avoiding the use of precision masking during layer deposition for some or all layers and avoiding the need to co-deposit emissive materials at low relative concentrations in some layers.

### BRIEF DESCRIPTION OF THE DRAWINGS

FIG. 1A depicts a simple untreated (by heat) device with a blue light emitting layer, buffer layer, non-emissive layer structure;

FIG. 1B shows a device of FIG. 1A after heating where the green emitter in the non-emissive layer has diffused through the buffer layer towards the previously blue light-emitting layer which has become a green light-emitting layer;

FIG. 2A depicts an untreated (by heat) embodiment of the present invention having a blue light-emitting layer and two patterned non-emissive source layers, one with a green emitter and one with a red emitter where both non-emissive layers are on the same side of the blue light emitting layer;

FIG. 2B shows the device of FIG. 2A after heating wherein both the green and red light emitting dopants have diffused from their respective non-emissive layers and converting that region of the blue light emitting layer into green and red light emitting regions; thus creating a RGB pixilated device;

FIG. 3A depicts another untreated (by heat) embodiment of the present invention having a blue light-emitting layer and non-emissive source layers, one with a green emitter and one with a red emitter where both non-emissive layers are on the opposite sides of the blue light emitting layer;

FIG. 3B shows the device of FIG. 3A after heating only in selected zones wherein both the green and red light emitting dopants have diffused from their respective non-emissive layers only in the regions heated and converting those regions of the blue light emitting layer into green and red light emitting regions; thus creating a RGB pixilated device;

FIG. 4 shows the results of heating experimental device example 1 at various times and temperatures;

FIG. 5 shows initial emission spectrum of device example 2;

FIG. 6 shows emission spectrum of device example 2 after 110° C. heating for 15 min;

FIG. 7 shows emission spectrum of device example 2 after additional 115° C. heating for 15 min; and

FIG. 8 shows emission spectrum of device example 2 after additional 115° C. heating for 16 h.

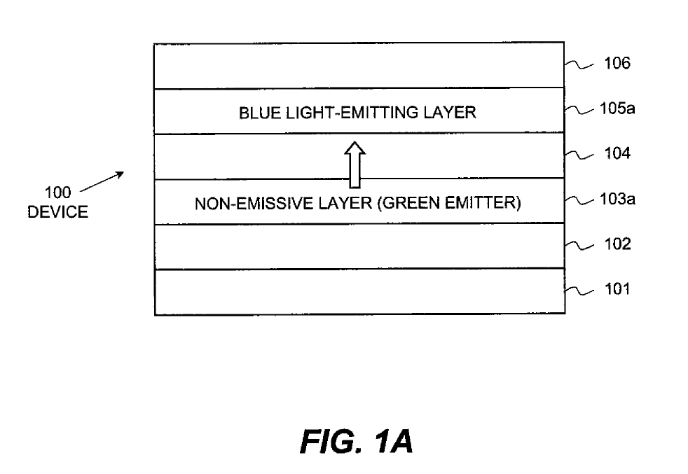

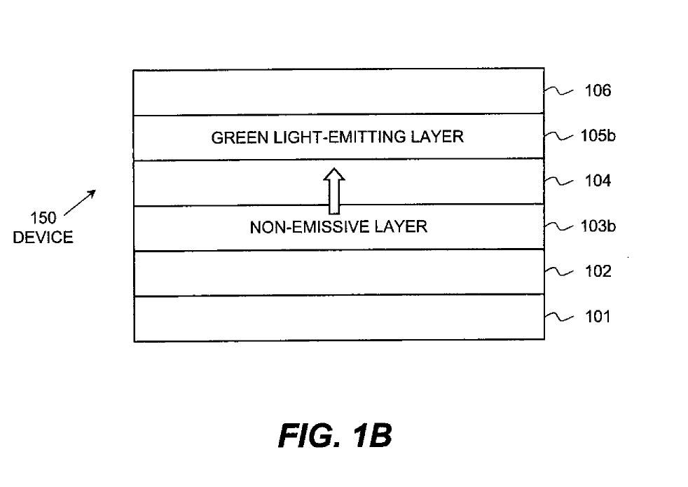

It will be understood that the FIGS. 1-3 above are not to scale since the individual layers are too thin and the thickness differences of various layers are too great to permit depiction to scale.

### DETAILED DESCRIPTION OF THE INVENTION

In the following discussion, blue light should be generally understood as being light with a wavelength in the range of about 400-500 nm, green light as being light with a wavelength in the range of about 500-600 nm and red light as light with a wavelength in the range of about 600-700 nm. Color can also often be defined in terms of CIE (Commission Internationale de L'Eclairage) 1931 coordinates as is well known in the art. Blue emission is generally understood to have CIE_{x,y} coordinates in the range of about (0.08 and 0.20), (0.00-0.20), green emission is in the range of about (0.24-0.36), (0.60-0.70) and red emission is in the range of about (0.60-0.70), (0.30-0.40). In terms of white light, desirable CIE_{x,y}coordinates are about (0.30-0.35), (0.30-0.35). A RGB OLED device overall produces the effect of white light by providing a mix of individual pixels (discrete regions), which individually emits R (red), G (green) and B (blue) light. A non-emissive layer means that the layer provides less than 25%, desirably less than 10% and most desirable, less than 5% of the total amount of light produced by the device. Emission from a particular layer containing known components is usually easy to determine from inspection of the spectrum of the light output.

In this invention, a light-emitting layer in a multicolored OLED device, preferably a red, green and blue (RGB) light emitting OLED device, can be formed where the color of light emitted can be modified by a thermal treatment after fabrication. In particular, the light-emitting layer in the OLED contains an emissive material (also known as a dopant) that emits blue light and is in direct contact with a non-emissive buffer layer which is in further direct contact with a non-emissive layer that contains a second emissive material that emits light of longer wavelength than blue light. Without any thermal post-fabrication treatment, this device will only emit blue light via energy transfer generated by hole-electron recombination to the blue emissive material. Due to the buffer layer, the longer wavelength emissive material is too far away from the hole-electron recombination for effective energy transfer and so there is no emission from this material in this layer. However, if the device is heated so that the second (longer wavelength) emissive material can diffuse into the buffer layer or even directly into the light-emitting layer that already contains a blue light-emitting material, then energy transfer will occur to the lower energy (longer wavelength) light-emitting material at the expense of the higher energy (shorter wavelength) blue light-emitting material. This will cause the color of the light emitted from this layer (or at its boundary with the buffer layer) to shift from blue to a different color. This is what is meant by the second (longer wavelength) emissive material diffusing into at least the buffer layer which in direct contact with the first (blue) emissive layer.

It should be understood that the hole-electron recombination energy preferentially transfers to an emitting species with the lowest excited singlet-state energy. The excited singlet-state energy is defined as the difference in energy between the emitting singlet state and the ground state. Generally, blue light-emitting materials will have higher excited singlet-state energy than a green light-emitting material which in turn is higher yet than a red light-emitting material.

The light emitting layer also desirably contains a non-emitting host material with higher excited singlet-state energy than either the blue emissive material or the second emissive material. Suitably, host materials are electron-transporting materials and there can be more than one host material present. Examples of host materials include metal oxinoids such as Alq and anthracenes. The thickness of the emitting layer is not critical but is generally in the range of 2-60 nm thick. The light-emitting layer can be formed by conventional vapor deposition (evaporation, sublimation) and, alternatively, by other coating of a polymeric organic light-emitting material.

There can be more than one blue emissive material present in the light-emitting layer and the total amount is generally in the range of 0.5% to 20% by volume. The blue emissive material can be fluorescent or phosphorescent. Classes of suitable blue light-emitting materials include perylenes, fluoranthenes, bis(azinyl)imine boron compounds, bis(azinyl)methene compounds and aminostyryl compounds. Some illustrative examples of useful blue light-emitting compounds are:

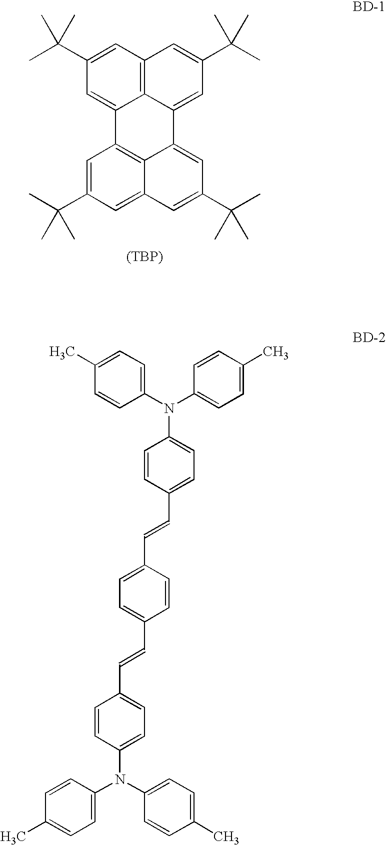

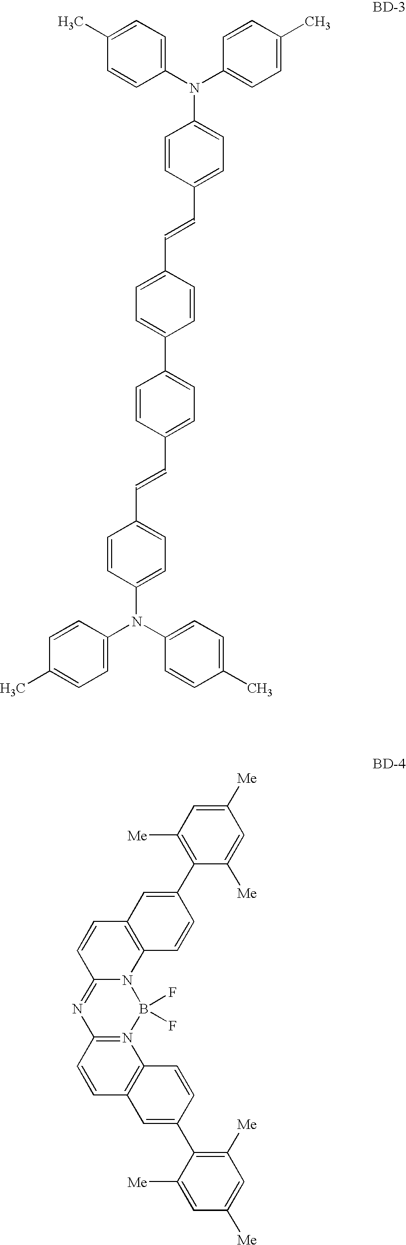

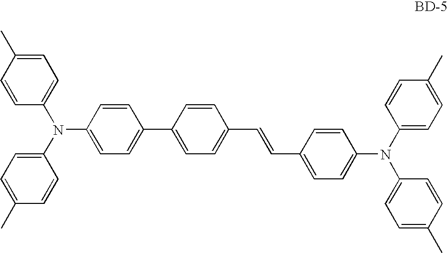

There is a buffer layer that separates the light-emitting layer with the blue emissive material and the non-emissive layer that contains the diffusible long wavelength emissive materials. This buffer layer should not contain any emissive materials during fabrication and before thermal treatment. After thermal treatment, long wavelength emissive materials from the neighboring non-emissive layer diffuse into or through this buffer layer and it can become emissive in those regions. If there is no long wavelength emissive material present after thermal treatment, then the buffer layer should be non-emissive in those regions. It should be understood that during the thermal treatment that it is possible that some of the blue emissive material can diffuse from the directly adjacent blue emitting layer, so that the buffer layer can emit some blue light near the interface of these two layers.

The buffer layer can be located either above or below the blue light-emitting layer; that is, it can be located either on the anode or cathode side. The thickness of the buffer layer should be in the range of 0.5-100 nm and preferably in the range of 5-10 nm.

Since the method requires the thermal diffusion of a long wavelength emitter into or through the buffer layer, physical properties (such as T_{g}, density and polarity) of material used in the buffer layer are important. Desirably, this buffer layer is composed of hole-transporting materials, preferably a single material. Polymers can also be used in the buffer layer since diffusion of compounds in polymers is well understood.

The hole-transporting materials of the buffer layer are suitably an aromatic tertiary amine. The aromatic tertiary amine can be an arylamine, such as a monoarylamine, diarylamine, triarylamine, or a polymeric arylamine. Preferred class of aromatic tertiary amines include those represented by structural formula (A).

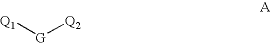

wherein Q₁ and Q₂ are independently selected aromatic tertiary amine moieties and G is a linking group such as an arylene, cycloalkylene, or alkylene group of a carbon to carbon bond. In one embodiment, at least one of Q₁ or Q₂ contains a polycyclic fused ring structure, e.g., a naphthalene or carbazole. When G is an aryl group, it is conveniently a phenylene, biphenylene, or naphthalene moiety.

Another useful class of triarylamines satisfying structural formula (A) and containing two triarylamine moieties is represented by structural formula (B):

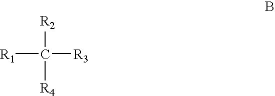

where R₁ and R₂ each independently represents a hydrogen atom, an aryl group, or an alkyl group or R₁ and R₂ together represent the atoms completing a cycloalkyl group; and R₃ and R₄ each independently represents an aryl group, which is in turn substituted with a diaryl substituted amino group, as indicated by structural formula (C):

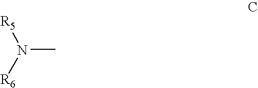

wherein R₅ and R₆ are independently selected aryl groups. In one embodiment, at least one of R₅ or R₆ contains a polycyclic fused ring structure, e.g., a naphthalene, or together form a carbazole group.

Another class of aromatic tertiary amines is the tetraaryldiamines. Desirable tetraaryldiamines include two diarylamino groups, such as indicated by formula (C), linked through an arylene group. Useful tetraaryldiamines include those represented by formula (D).

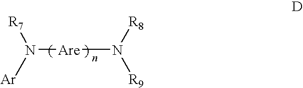

wherein each Are is an independently selected arylene group, such as a phenylene or anthracene moiety, n is an integer of from 1 to 4, and Ar, R₇, R₈, and R₉ are independently selected aryl groups. In a typical embodiment, at least one of Ar, R₇, R₈, and R₉ is a polycyclic fused ring structure, e.g., a naphthalene.

Illustrative of useful hole transporting aromatic tertiary amines are the following: 1,1-Bis(4-di-p-tolylaminophenyl)cyclohexane (TAPC); 1,1-Bis(4-di-p-tolylaminophenyl)-3-phenylpropane (TAPPP); 1,4-bis[2-[4-[N,N-di(p-toly)amino]phenyl]vinyl]benzene (BDTAPVB); N,N,N′,N′-Tetra-p-tolyl-4,4′-diaminobiphenyl (TTB); 4,4′-Bis[N-(1-naphthyl)-N-phenylamino]biphenyl (NPB); 4,4′-Bis[N-(1-naphthyl)-N-(2-naphthyl)amino]biphenyl (TNB); 4,4′,4″-tris[(3-methylphenyl)phenylamino]triphenylamine (MTDATA) and 4,4′-Bis[N-(3-methylphenyl)-N-phenylamino]biphenyl (TPD). In addition, polymeric hole-transporting materials can be used such as poly(N-vinylcarbazole) (PVK), polythiophenes, polypyirole, polyaniline, and copolymers such as poly(3,4-ethylenedioxythiophene)/poly(4-styrenesulfonate) also called PEDOT/PSS.

Immediately adjacent to, and in direct contact with the buffer layer, is a non-emissive layer that contains an emissive material that is capable of emitting light at wavelengths longer than blue light. It is highly preferred that this non-emissive layer does not emit any significant amounts (less than 5% of the total amount of light produced by the device) before or after thermal treatment. The purpose of this layer to provide a source of long wavelength emissive material that upon thermal treatment, it diffuses to a region of the device where it can emit light. There can be more than one material capable of emission in this layer and the emission of any additional emitter can be in the same or in a different region of light. The thickness of this non-emissive layer should be in the range of 5-100 nm and preferably in the range of 20-40 nm.

Light with wavelengths longer than blue light are greater than 500 nm and includes green and red light as well as other colors such as orange or yellow. Materials that are capable of emitting either green or red light are preferred. “Capable of emitting” means that the material, when located in the non-emissive layer (without regard to whether the device has been thermally treated), does not emit significant amounts of light when a current/voltage source is applied to the device. However, after thermal treatment, that portion of the material that has migrated or diffused to the vicinity of the blue emissive layer now emits light that is longer in wavelength than blue.

The material capable of emitting light at wavelengths longer than blue light can either be fluorescent or phosphorescent, although fluorescent are preferred. Although the term “fluorescent” is commonly used to describe any light-emitting material, in this case it refers to a material that emits light from a singlet excited state and “phosphorescent” refers to a material that emits light from an excited state of higher multiplicity.

Some longer wavelength fluorescent emitting materials include, but are not limited to, derivatives of anthracene, aminoanthracene, tetracene, xanthene, perylene, rubrene, coumarin, rhodamine, and quinacridone, dicyanomethylenepyran compounds, thiopyran compounds, polymethine compounds, pyrylium and thiapyrylium compounds, fluorene derivatives, periflanthene derivatives, indenoperylene derivatives and bis(azinyl)amine boron compounds. Suitable fluorescent dopants can also be found in Chen, Shi, and Tang, “Recent Developments in Molecular Organic Electroluminescent Materials,” Macromot Symp. 125, 1 (1997) and the references cited therein; Hung and Chen, “Recent Progress of Molecular Organic Electroluminescent Materials and Devices,” Mat. Sci. and Eng R39, 143 (2002) and the references cited therein.

Illustrative examples of useful materials include, but are not limited to, the following:

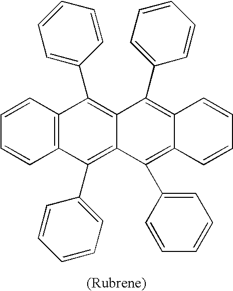

FD-5

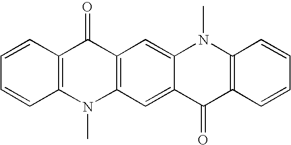

FD-6

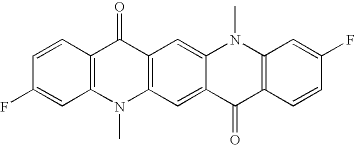

FD-7

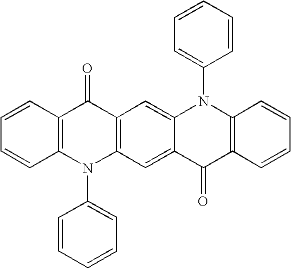

FD-8

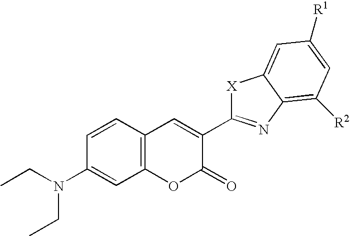

| | X | R1 | R2 |
|---|---|---|---|
| FD-9 | O | H | H |
| FD-10 | O | H | Methyl |
| FD-11 | O | Methyl | H |
| FD-12 | O | Methyl | Methyl |
| FD-13 | O | H | t-butyl |
| FD-14 | O | t-butyl | H |
| FD-15 | O | t-butyl | t-butyl |
| FD-16 | S | H | H |
| FD-17 | S | H | Methyl |
| FD-18 | S | Methyl | H |
| FD-19 | S | Methyl | Methyl |
| FD-20 | S | H | t-butyl |
| FD-21 | S | t-butyl | H |
| FD-22 | S | t-butyl | t-butyl |
| 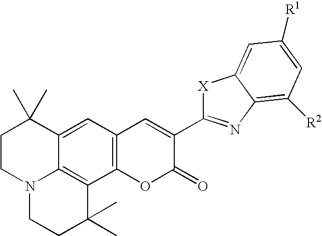 | | | |
| | X | R1 | R2 |
| FD-13 | O | H | H |
| FD-24 | O | H | Methyl |
| FD-25 | O | Methyl | H |
| FD-26 | O | Methyl | Methyl |
| FD-27 | O | H | t-butyl |
| FD-28 | O | t-butyl | H |
| FD-29 | O | t-butyl | t-butyl |
| FD-30 | S | H | H |
| FD-31 | S | H | Methyl |
| FD-32 | S | Methyl | H |
| FD-33 | S | Methyl | Methyl |
| FD-34 | S | H | t-butyl |
| FD-35 | S | t-butyl | H |
| FD-36 | S | t-butyl | t-butyl |

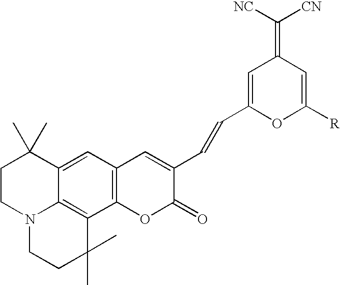

| | R |
|---|---|
| FD-37 | phenyl |
| FD-38 | methyl |
| FD-39 | t-butyl |
| FD-40 | mesityl |

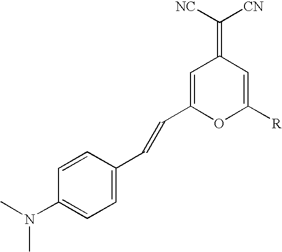

| | R |
|---|---|
| FD-41 | phenyl |
| FD-42 | methyl |
| FD-43 | t-butyl |
| FD-44 | mesityl |

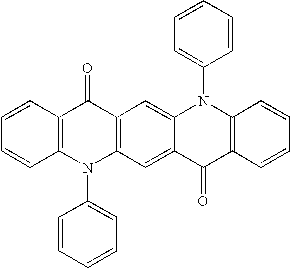

FD-45

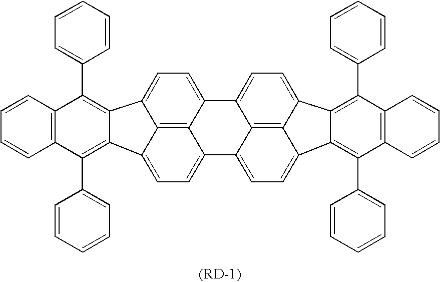

FD-46

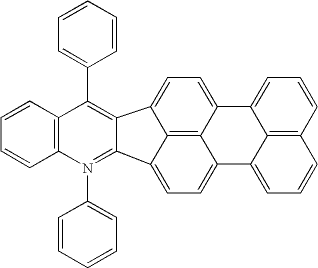

FD-49

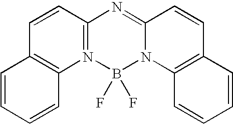

FD-50

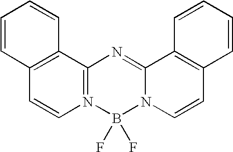

FD-51

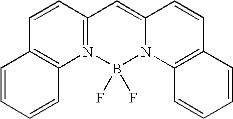

FD-52

Courmarins represent a useful class of green-emitting dopants as described by Tang et al. in U.S. Pat. Nos. 4,769,292 and 6,020,078. Quinacridones represent another useful class of green-emitting dopants. Useful quinacridones are described in U.S. Pat. Nos. 5,593,788; 6,664,396; 7,026,481, U.S. Patent Application Publication No. 2004/0001969 and JP 09-13026A.

The non-emissive layer can also contain other materials such as non-emitting host molecules in addition to the material that is capable of emitting light. Preferably, it is a hole-transporting material and even more preferably, it is the same hole-transporting material that is used in the buffer layer.

In some embodiments, there is more than one non-emissive layer with materials capable of emitting long wavelength light present in the device. Preferably, one non-emissive layer contains a material capable of emitting green light and another contains a material capable of emitting red light. However, neither non-emissive layer can be adjacent to or in direct contact with the blue emissive layer and both must be separated from the blue emissive layer by at least one non-emissive buffer layer. In the embodiments with more than one non-emissive emitter source layer, they can be on the same side of the blue emitting layer or on different sides. Although not always necessary, when the non-emissive source layers are located on the same side, it is desirable to separate the two non-emissive source layers by an additional buffer layer. This additional buffer layer has the same requirements as the buffer layer located between one of the non-emissive source layer and the blue emitting layer. In this embodiment, it is desirable that in the following sequence: 2^{nd} non-emissive layer/buffer layer/1^{st} non-emissive layer/buffer layer/blue light-emitting layer, there are no other intermediate layers between them.

The non-emissive layer can be formed by conventional vapor deposition and, alternatively, by thermally induced transfer from a dopant donor layer formed on a donor support or other printing methods such as ink jet, gravure, offset, screen, flexographic, or xerographic printing.

Diffusion of a material or materials capable of emitting long wavelength light from the non-emissive layer(s) into or through the buffer layer so that the material is in contact with the blue light emitting layer by a heat treatment process of the completed device requires relatively simple equipment and provides accurate control of processing to achieve uniform diffusion. Heating can be performed by a variety of methods including, but not limited to heating on a hot plate, oven, infrared lamp, flash lamp, and laser. The temperature range is 50° C. to 250° C. with an optimal temperature near the glass transition point (T_{g}) of the materials.

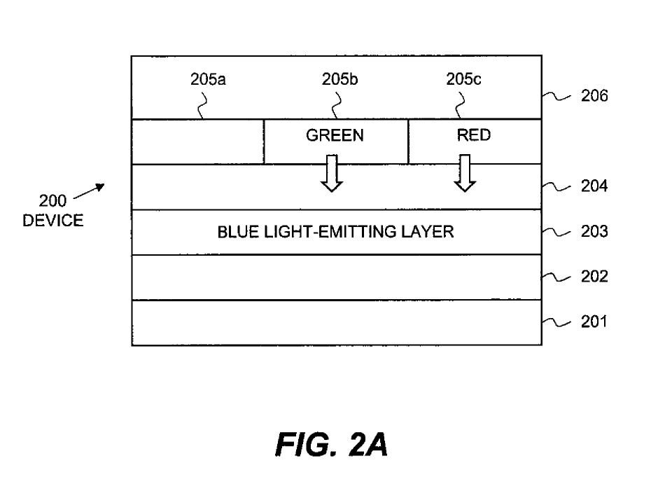

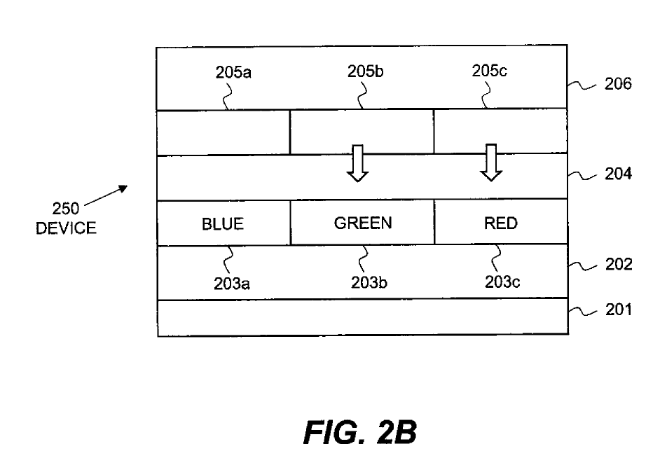

In one desirable embodiment, the non-emissive layer(s) are patterned; that is, they are not continuous over all of the light emitting parts of the device whereas the blue light emitting layer is unpatterned and continuous over all of the light emitting parts of the device. In this way, thermal treatment of the device to cause diffusion will result in a patterned device. For example, in a device with a patterned non-emissive layer containing a material capable of green emission in addition to an uniform blue-light-emitting layer, only blue light will be emitted from the areas where only the blue light-emitting layer is present, but in areas where the non-emissive layer is also present, thermal treatment will cause the green light-emitting molecule to diffuse out of the non-emissive layer into or through the buffer layer to be in contact with the blue light-emitting layer, at which point, energy transfer will occur preferentially to the green light emitter instead of the blue emitter and only green light will be emitted in that region. Thus, a pattern of blue and green pixels is created thermally corresponding to the pattern of non-emissive source layer. This method can be extended to devices with a continuous blue light emitting layer and patterned non-emissive source layers with green and red emitters (see FIGS. 2A and 2B). By using different patterns for the green and red source layers, a pixellated RGB device can be created using thermal treatment.

In an alternative embodiment, patterned devices can be created from devices where both the blue light-emitting layer and the non-emissive source layer(s) are unpatterned and continuous over the light-emitting area of the device. This is accomplished by selectively heating only the areas where it is desired to change the color of the light emitted from blue to a longer wavelength color. In this case, masking or selective laydown of layers in only certain areas is no required, resulting is a simplified manufacturing process.

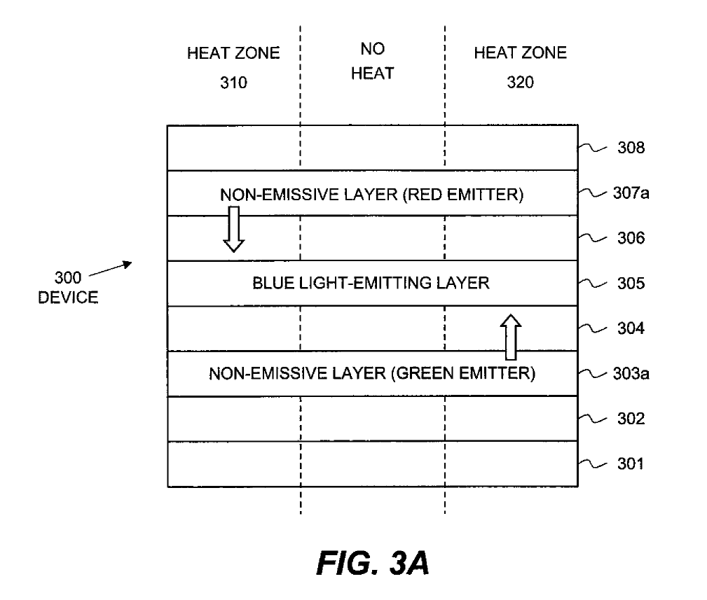

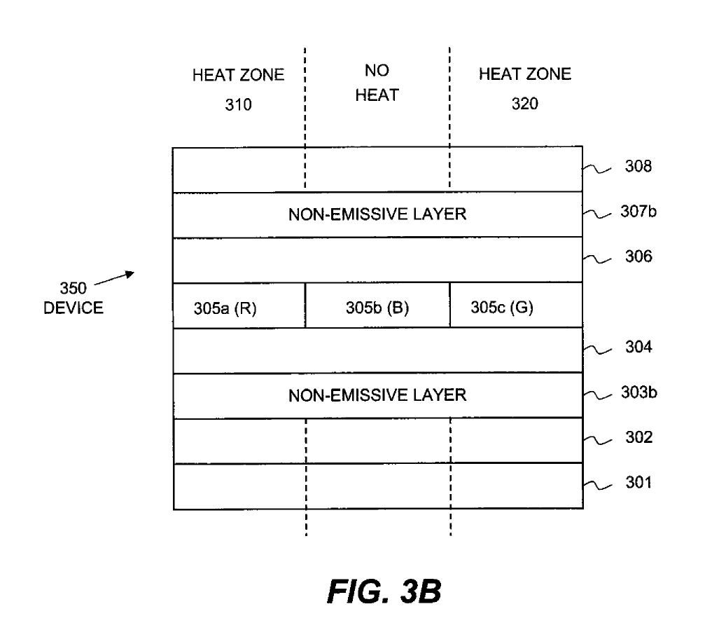

For example, in a device with a blue light emitting and a non-emissive layer containing a material capable of green emission, both being laid down in a uniform fashion, only blue light will be emitted from the areas where there is no thermal treatment, but in thermally treated areas, the green light-emitting material is diffused out of the non-emissive layer into or through the buffer layer to be in contact with the blue light-emitting layer, at which point, energy transfer will occur preferentially to the green light emitter instead of the blue emitter and only green light will be emitted in that region. Thus, a pattern of blue and green pixels is created corresponding to the pattern of thermal exposure. This method can be extended to devices with a continuous blue light emitting layer and two non-emissive source layers with green and red emitters (see FIGS. 3A and 3B). By heating only selected areas, a pixellated RGB device can be created. In this case, it can be necessary to selectively heat different areas with separate conditions or methods since the different emitters can have different diffusion characteristics.

Since all of the embodiments require thermal diffusion of emitters from one layer to another, it is important to reduce spreading or smearing during diffusion. There are many methods that can be useful to control diffusion including using thin buffer layers, choice of buffer material and its characteristics such as T_{g}, choice of host material (if any) in the non-emissive source layer and choice of longer wavelength emitter characteristics that affect diffusion such as molecular weight and polarity.

Turning now to FIGS. 1A and 1B, there are shown devices which illustrate processing steps for making an organic light-emitting device in accordance with the present invention.

In FIG. 1A, an organic light-emitting device 100 as fabricated but before any thermal treatment shows, in sequence, a substrate 101, an anode 102, a non-emissive layer containing a material capable of green light emission 103a, a buffer layer 104, a blue light emitting layer 105a and a cathode 106. The anode 102 and cathode 106 are electrically connected to a power/voltage source (not shown). The direction of diffusion of the green emitter material from layer 103a upon heating, is shown by an arrow.

FIG. 1B schematically illustrates an organic light emitting structure 150 which is formed after heating the organic light-emitting device 100. Here, the green emissive material has diffused from a non-emissive layer 103b into buffer layer 104 and a blue-light emitting layer 105b. Layer 105b emitted blue light prior to heating but because of the presence of the green light emitter now emits green light. It should be noted that layer 103b can contain some residual green emitting material, but the layer is still non-emissive since it is located too far from layer 105b where recombination is occurring.

Turning now to FIGS. 2A and 2B, there are shown devices which illustrate processing steps which, taken together, illustrate another aspect of the present invention for making an organic light-emitting device with additional layers.

FIG. 2A shows the untreated organic light-emitting device 200 which is similar to device 100 except that the non-emissive layer has been patterned into three regions: 205a which contains no material capable of emitting light, 205b which contains material capable of emitting green light and 205c which contains material capable of emitting red light. Also present is a substrate 201, an anode 202, a blue light emitting layer 203 and a buffer layer 204. A cathode 206 is provided as before. Upon uniformly heating the fabricated device 200, the red and green emitting materials diffuse as shown by the arrows.

FIG. 2B shows a resultant thermally treated organic light-emitting device 250 where the blue emitting layer 203 is unchanged in the vicinity of non-emissive layer 205a to create a blue light emitting region 203a. However, in the region of non-emissive layer 205b (containing green emissive material), the blue emitting layer 203 is converted to a green light emitting region 203b because of the diffusion of the green emissive material into contact with blue-light emitting layer 203. Similarly, in the region of non-emissive layer 205c (containing red emissive material), the blue emitting layer 203 is converted to a red light emitting region 203c because of the diffusion of the red emissive material into contact with blue-light emitting layer 203. In this way, a patterned RGB OLED device is formed. As before, regions 205b and 205c can contain some residual emitting materials, but the layers are still non-emissive since they are located too far from the regions 203, 203b and 203c where recombination is occurring.

Turning now to FIGS. 3A and 3B, there are shown devices which illustrate processing steps which, taken together, illustrate yet another aspect of the present invention for making an organic light-emitting device with additional layers.

FIG. 3A shows an untreated organic light-emitting device 300 as fabricated but before any thermal treatment composed of, in sequence, a substrate 301, an anode 302, a non-emissive layer containing a material capable of green light emission 303a, a buffer layer 304, a blue light emitting layer 305, a buffer layer 306, a non-emissive layer containing a material capable of red light emission 307a and a cathode 308. In this embodiment, the non-emissive layers 303a and 307a are continuous and not patterned. Thermal treatment of selected regions, as indicated by heat zones 310 and 320, is not uniform across the device. Heat Zone 310 is sufficient to cause diffusion of the red emitting material from layer 307a towards blue emitting layer 305 as shown by the arrow. Heat Zone 320 is sufficient to cause diffusion of the green emitting material from layer 303a towards blue emitting layer 305 as shown by the arrow. Heat zones 310 and 320 can represent different conditions and methods.

FIG. 3B shows the resultant thermally treated organic light-emitting device 350 where the blue emitting layer 305 is unchanged in the region where there was no heating (305b). However, in the region of heat zone 310, the blue emitting layer 305 is converted to a red light emitting region 305a because of the diffusion of the red emissive material into contact with blue light emitting layer 305. In the heated region, layer 307b contains no or less material capable of red emission than layer 307a since the material has diffused away from this layer. Similarly, in the region of heat zone 320, the blue emitting layer 305 is converted to a green light emitting region 305c because of the diffusion of the green missive material into contact with blue light emitting layer 305. In the heated region, layer 303b contains no or less material capable of green emission than layer 303a since the material has diffused away. In this way, a patterned RGB OLED device is formed. It should be noted that in those regions where layers 303b and 307b were not heated or insufficiently heated to cause diffusion of the emitter, these regions remain non-emissive since they are located too far from the regions 305a, 305b and 305 where recombination is occurring.

### EXAMPLES

The following examples are presented for a further understanding of the invention. For purposes of clarity, the material and the layers formed therefrom will be as indicated below.

| | |
|---|---|
| ITO | indium tin oxide |
| | (anode) |
| NPB | 4,4′-bis-[N-(1-naphthyl)-N-phenylamino]-bi-phenyl |
| | (hole transporting material) |
| TPD | 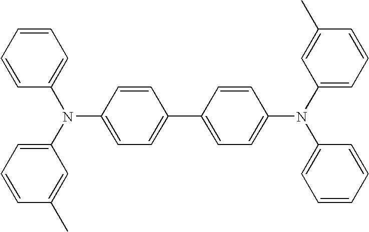 |
| | (hole transporting material) |
| TAPC | 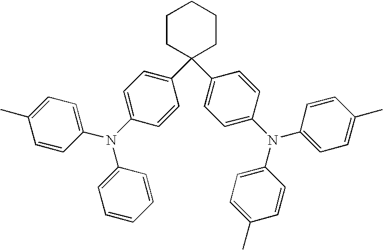 |
| | (hole transporting material) |
| Alq | tris(8-quanolinato-N1,08)-aluminum |
| | host, electron-transporting material |
| GD-1 | 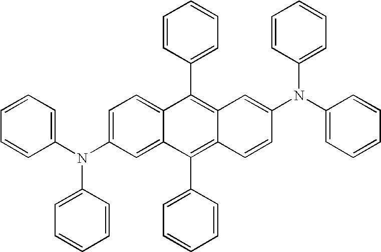 |
| | (green emitter) |
| RD-1 | 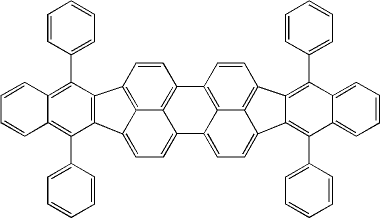 |
| | (red emitter) |
| Host-1 | 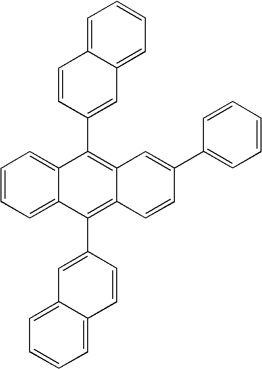 |
| | (host, electron-transporting material) |

### Example 1

A device was constructed as follows using conventional vacuum evaporation in the following sequence:
1) a glass substrate coated with an 85 nm layer of indium-tin oxide (ITO), as the anode, was sequentially ultrasonicated in a commercial detergent, rinsed in deionized water, exposed to oxygen plasma for about 1 min, and coated with a 1 nm fluorocarbon (CFₓ) hole-injecting layer (HIL) by plasma-assisted deposition of CHF₃ as described in U.S. Pat. No. 6,208,075;
2) a 60 nm thick NPB layer hole transporting layer (HTL) was deposited over the ITO anode;
3) a 30 nm thick non-emissive layer (NEL) of 93% NPB and 7% GD-1 was formed over HTL;
4) a 15 nm thick buffer layer of NPB was formed over the NEL;
5) a 20 nm thick blue light-emitting layer (BLEL) of 99.2% Host-1 and 0.8% BD-4 was formed over HTL2;
6) a 32.5 nm thick first electron transporting layer (ETL1) of Host-1 was then formed over the BLEL;
7) a 2.5 nm second electron transporting layer (ETL2) of Alq was then formed over ETL1; and
8) a 150 nm thick cathode of Al was then formed over ETL2.

The above sequence completed the deposition of the EL device. The device was then hermetically packaged in a dry glove box for protection against ambient environment.

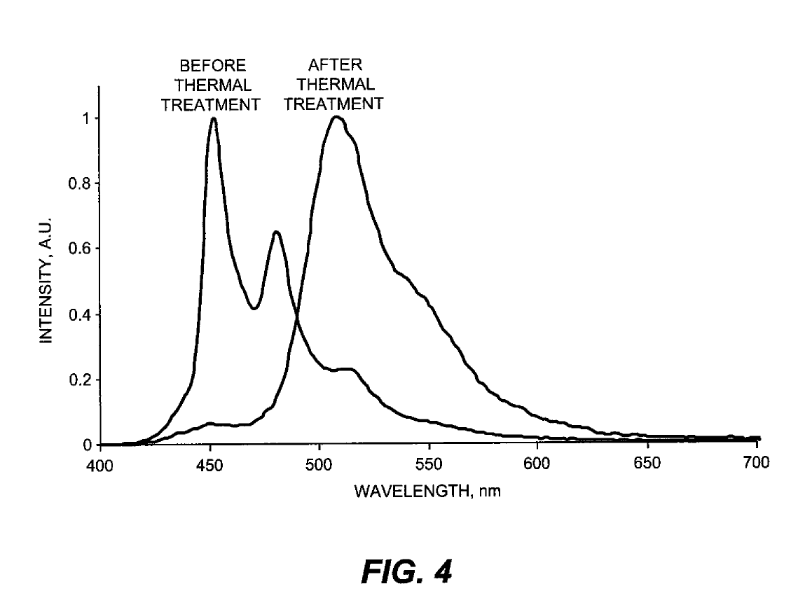

FIG. 4 shows that before the heat treatment, the device emitted primarily blue light with a drive voltage of 6.0 V and an EQE (the external quantum efficiency (EQE) is the ratio of photons emitted per electrons injected into OLED device, expressed as percentage calculated from the photon flux measured normal to the OLED surface with assumption that an OLED is a Lambertian emitter) of 6.7%. This also illustrates that the layer containing the green-dopant was non-emissive. This device was then heated in precision temperature controlled oven with forced airflow for 4 hours at 110° C. followed by 2 hours at 115° C. and 1 hour at 120° C. After heat treatment, the device emitted primarily green light with a drive voltage of 6.1 V and an EQE of 6.7%. Heat treatment caused the green dopant to diffuse into the adjacent layers sufficiently so that the hole-electron recombination energy generated in the LEL was now preferably transferred to the lower bandgap energy green dopant compared to the blue dopant which is still present in the LEL.

### Example 2

Another device was constructed in a manner similar to Example 1 as follows:
1) a glass substrate coated with an 85 nm layer of indium-tin oxide (ITO), as the anode, was sequentially ultrasonicated in a commercial detergent, rinsed in deionized water, exposed to oxygen plasma for about 1 min, and coated with a 1 nm fluorocarbon (CFx) hole-injecting layer (HIL) by plasma-assisted deposition of CHF3 as described in U.S. Pat. No. 6,208,075;
2) a first 35 nm thick non-emissive layer (NEL1) of 98.3% NPB and 1.7% RD-1 was formed over HIL;
3) a 15 nm thick buffer layer (BL1) of NPB was formed over NEL1;

4) a second 30 nm thick non-emissive layer (NEL2) of 93% TAPC and 7% GD-1 was formed over the buffer;
5) a 5 nm thick buffer layer (BL2) of TAPC was formed over NEL2;
6) a 20 nm thick blue light-emitting layer (BLEL) of 99.2% Host-1 and 0.8% BD-4 was formed over BL2;
8) a 32.5 nm thick first electron transporting layer (ETL1) of Host-1 was then formed over the BLEL;
9) a 2.5 nm second electron transporting layer (ETL2) of Alq was then formed over ETL1; and
10) a 150 nm thick cathode of Al was then formed over ETL2.

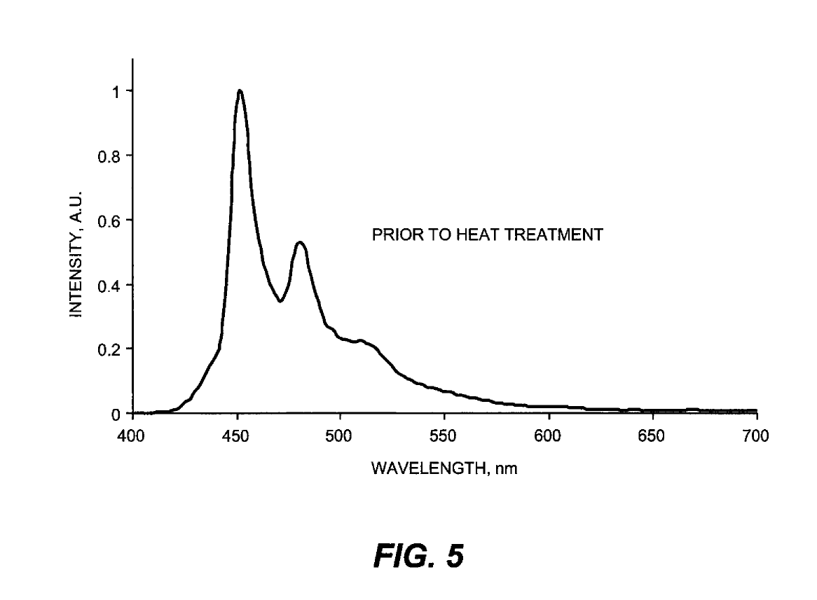

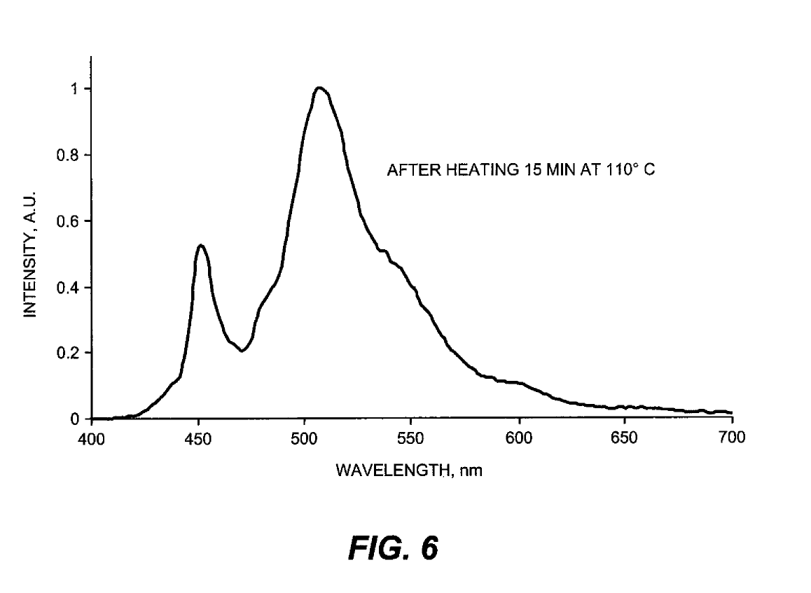

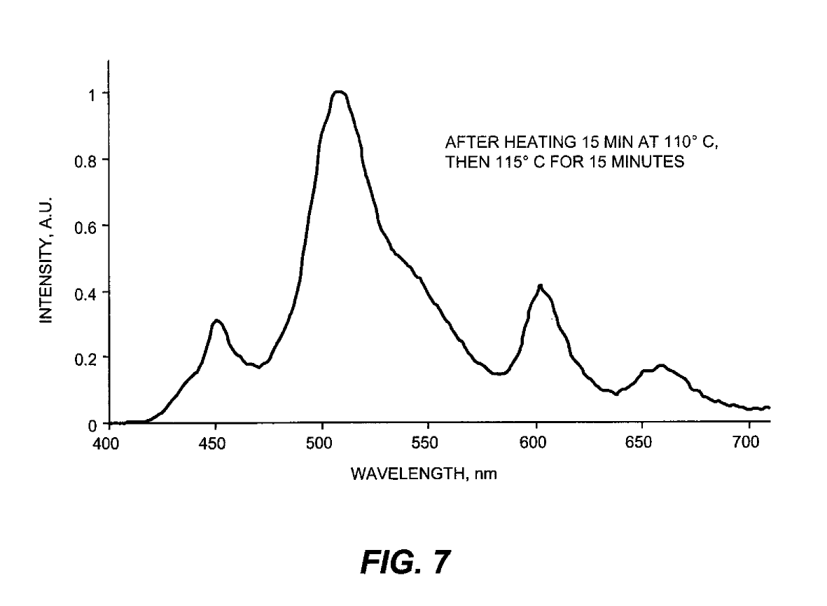

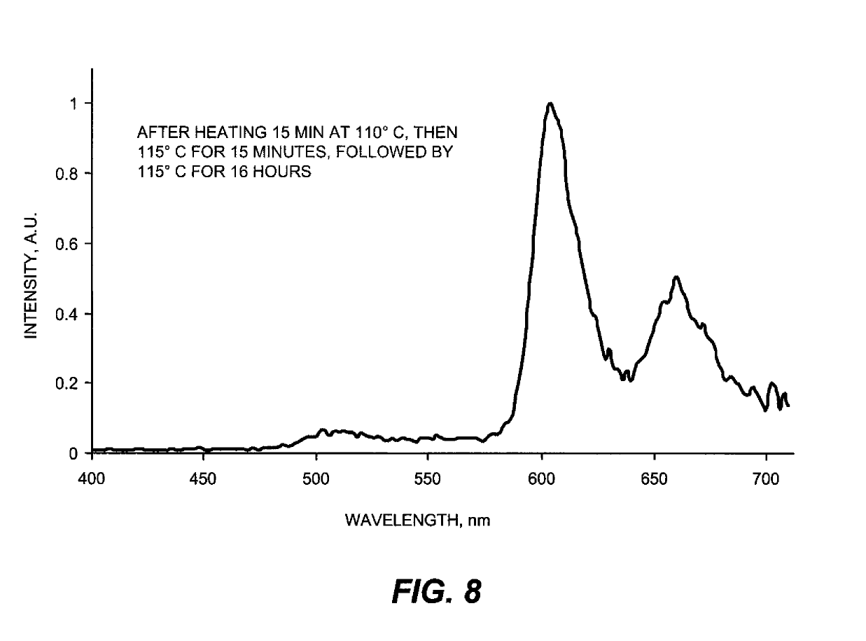

As shown in FIG. 5, before the heat treatment, the device emitted primarily blue light with a drive voltage of 6.1 V and an EQE of 5.8%. After heating the device for 15 min at 110° C., the device emitted primarily green light with a drive voltage of 6.1 V and an EQE of 5.6% with some blue and almost no red emission (FIG. 6). Additional heating at 115° C. for 15 minutes significantly increased the amount of red emission (FIG. 7), resulting in 6.3 V drive voltage and 3.9% EQE. After continuing heating at 115° C. for 16 hours, the device emitted primarily red light with a drive voltage of 8.3 V and an EQE of 0.31% (FIG. 8). These experimental results indicate that before the post-fabrication heat treatment, the layers containing the green dopant or red dopant were non-emissive. Depending on the heat treatment, either dopant was diffused from its NEL layer into the buffer adjacent to the blue emitting layer or into the blue emitting layer sufficiently so that the hole-electron recombination energy generated in the LEL was now preferably transferred to the lower bandgap energy green or red dopant compared to the blue dopant which is still present in the LEL. In this way, the color of the light emitted from a single LEL could be varied from blue to green to red, as well as intermediate mixtures of the three, depending on the thermal treatment.

The invention has been described in detail with particular reference to certain preferred embodiments thereof, but it will be understood that variations and modifications can be effected within the spirit and scope of the invention.

### Parts List

100 OLED as fabricated, prior to heat treatment
101 Substrate
102 Anode
103a Non-emissive layer containing green emitter prior to heat)
103b Non-emissive layer containing green emitter (after heat)
104 Buffer Layer
105a Blue Light-Emitting layer
105b Green Light-Emitting layer
106 Cathode
150 OLED 100 after heat treatment
200 OLED as fabricated, prior to heat treatment
201 Substrate
202 Anode
203 Blue Light-Emitting Layer
203a Blue Light Emitting Region
203b Green Light Emitting Region
203c Red Light-emitting Region
204 Buffer Layer
205a Non-emissive region (does not contain emitter material)
205b Non-emissive region (contains green emitter material)
205c Non-emissive region (contains red emitter material)
206 Cathode
250 OLED 200 after heat treatment
300 OLED as fabricated, prior to heat treatment
301 Substrate
302 Anode
303a Non-emissive Layer (contains green emitter)

### Parts List Cont'd

303b Non-emissive Layer (may or may not contain green emitter) after partial heat treatment
304 Buffer Layer
305 Blue Light-emitting Layer
305a Red Light Emitting Region
305b Blue Light Emitting Region
306 Buffer Layer
306c Green Light-emitting Region
307a Non-emissive Layer (contains red emitter)
307b Non-emissive Layer (may or may not contain red emitter) after partial heat treatment
308 Cathode
310 1^{st} Heat Zone
320 2^{nd} Heat Zone
350 OLED 300 after heat treatment

1. In a method of making an organic electroluminescent device producing at least two colors of light having an anode and a cathode on a substrate, and at least one emission layer, located between the anode and cathode, containing a first emissive material that emits blue light, the improvement comprising:
(a) providing at least one non-emissive layer containing a second emissive material that is capable of emitting light longer in wavelength than blue light and disposed over or under the blue emission layer;
(b) providing a buffer layer between the non-emissive layer and the emissive layer and in direct contact with both; and
(c) heating the electroluminescent device to cause the second emissive material from the non-emissive layer to diffuse into at least the buffer layer so that second emissive material emits light.

2. The method of claim 1 wherein the second emissive material of step (a) is capable of emitting green light.

3. The method of claim 1 wherein the second emissive material of step (a) is capable of emitting red light.

4. The method of claim 1 wherein the buffer layer of step (b) includes a hole-transporting material.

5. The method of claim 1 wherein the non-emissive layer of step (a) is deposited in a pattern so that after heating according to step (c), different patterned portions are formed that correspond to different colored light emitting pixels.

6. The method of claim 1 wherein there is a second non-emissive layer containing a third emissive material that is capable of emitting light longer in wavelength than the second emissive material in the non-emissive layer of step (a).

7. The method of claim 6 wherein the second emissive material is capable of emitting green light and the third emissive material is capable of emitting red light.

8. The method of claim 7 wherein the following sequence of layers is formed: emissive layer that contains the first blue emissive material, a first buffer layer according to step (b), a first non-emissive layer having a second emissive material which is capable of emitting green light according to step (a), a second non-emissive buffer layer and a second non-emissive layer having a third emissive material which is capable of emitting red light.

9. The method of claim 8 wherein at least one of the non-emissive layers containing the materials capable of emitting green or red light is deposited in a pattern so that after heating according to step (c), different patterned portions are formed that correspond to different colored light emitting pixels.

10. The method of claim 9 wherein both the non-emissive layers that contain the materials capable of emitting green or red light are deposited in a pattern so that after heating according to step (c), different patterned portions are formed that correspond to red and green colored light emitting pixels.

11. The method of claim 6 wherein the heating of step (c) is performed only in selected locations so where heated, different patterned portions are formed that correspond to red or green colored light emitting pixels and in unheated locations, only blue light is emitted from the emissive layer.

12. The method of claim 2 wherein the following sequence of layers is formed: a second non-emissive layer having an third emissive material capable of emitting red light, a non-emissive buffer layer, an emissive layer that contains the first blue emissive material, a buffer layer according to step (b), and a first non-emissive layer according to step (a).

13. The method of claim 12 wherein at least one of the non-emissive layers containing the materials capable of emitting green or red light is deposited in a pattern so that after heating according to step (c), different patterned portions are formed that correspond to different colored light emitting pixels.

14. The method of claim 13 wherein both the non-emissive layers that contain the materials capable of emitting green or red light are deposited in a pattern so that after heating according to step (c), different patterned portions are formed that correspond to red and green colored light emitting pixels.
